(19) United States
(12) Patent Application Publication
(10) Pub. No.: US 2008/0073757 A1
(43) Pub. Date: Mar. 27, 2008

(54) Semiconductor dies and methods and apparatus to mold lock a semiconductor die

(76) Inventors: Steven Alfred Kummerl, Carrollton, TX (US); Bernhard Peter Lange, Freising (DE); Jeffrey Gail Holloway, Plano, TX (US)

Correspondence Address: TEXAS INSTRUMENTS INCORPORATED, P O BOX 655474, M/S 3999, DALLAS, TX, 75265, US

(21) Appl. No.: 11/526,464

(22) Filed: Sep. 25, 2006

(51) Int. Cl. H01L 23/495; H01L 21/00

(52) U.S. Cl. 257/666; 257/787; 438/124; 257/E23.116

(57) ABSTRACT

Semiconductor dies and methods to mold lock a semiconductor die are disclosed. A disclosed example semiconductor die includes a top surface, a bottom surface, and a plurality of sides joining the top surface and the bottom surface. At least one of the sides includes an interference structure to mold lock the die in a package.

### FIELD OF THE DISCLOSURE

This disclosure relates generally to semiconductor fabrication and, more particularly, to semiconductor dies and methods to mold lock a semiconductor die.

### BACKGROUND

The production of integrated circuits involves multiple processes. For example, semiconductor devices, bonding pads and other circuitry are fabricated on a semiconductor wafer (e.g., a silicon wafer). Subsequently, the wafer is mounted on a wafer frame which, in turn, is mounted on a chuck of a stepper machine by, for example, vacuum force. Wafer saw streets are then marked on the wafer between the individual chips or dies of the wafer. The individual chips or dies are separated by using a saw to cut along the saw streets marked on the wafer. The stepper machine rotates the wafer in 90 degree increments relative to the saw during the cutting process to enable the saw to cut along all four sides of the rectangular dies of the wafer.

After the individual chip(s) or die(s) are cut from the wafer, the wafer frame is stretched. The individual chips or dies are then picked up and placed on a mounting strip such as a sticky carrier tape. The carrier tape holds the die in place via, for example, its bottom surface for testing, subsequent processing, or both testing and subsequent processing. The example prior art sawing method described above creates dies having substantially straight, vertical sides.

Before or after a die is placed on the carrier, other structures to be packaged with the die such as, for example, contact/mounting pads or other electrical components (e.g., other dies) are mounted on the carrier adjacent the die. In the case of applications employing wire bonding, any required contact leads are attached from the adjacent structures to bonding pads fabricated on the die. For example, a contact lead may be wire bonded from a bonding pad of the die to an adjacent contact pad.

After the interconnections between the die and the adjacent structures are completed, a mold is lowered onto the die and adjacent structures. A pellet of encapsulating material such as plastic is injected into the mold and melted. The melted encapsulating material flows throughout the mold cavity to encapsulate the die and the adjacent structures. The encapsulating material is then permitted to cool and solidify to thereby form a protective package around the die and the adjacent structures. Subsequently, the carrier tape is removed from the package. In this example, the completed package can be referred to as an exposed die package because the bottom surface of the die is not encapsulated, but is instead flush with the protective package.

### SUMMARY

Semiconductor dies and methods to mold lock a semiconductor die are disclosed. A disclosed example semiconductor die includes a top surface, a bottom surface, and a plurality of sides joining the top surface and the bottom surface. At least one of the sides includes an interference structure to mold lock the die in a package.

In some disclosed examples, the interference structure comprises an angled surface disposed at a non 90 degree angle relative to at least one of the top surface and the bottom surface. In some disclosed examples, the interference structure comprises a stepped side wall.

A disclosed example method of forming a semiconductor device comprises: cutting a wafer to define an interference structure at at least one side of a die; and separating the die from the wafer.

In some disclosed examples, the method further includes: positioning the separated die on a die carrier; mounting an electrical element on the die carrier in proximity to the die; and attaching a wire bond between the electrical element and the die.

In some disclosed examples, the method further includes: placing a mold over the die and the electrical element; and injecting an encapsulating material into the mold to mold lock the die in a package.

A disclosed example exposed die package includes: a die having a side defining an interference structure; and an encapsulating material at least partially engaging the interference structure to mold lock the die in the package.

### BRIEF DESCRIPTION OF THE DRAWINGS

FIGS. 1A-1C illustrate an example process to cut dies with interlocking sides from an example wafer.

FIGS. 2A-2B are side and top views, respectively, of the example wafer of FIGS. 1A-1C after being cut into example dies with interlocking sides.

FIGS. 3A-3C illustrate an example process of mounting an example die produced by the example process of FIGS. 1A-1C in an example exposed die package.

FIGS. 4A-4B are side and perspective cutaway views, respectively, of an example exposed die package prepared according to the example processes illustrated in FIGS. 1A-1C and FIGS. 3A-3C.

FIGS. 5A-5C illustrate another example process to cut dies with interlocking sides from an example wafer.

FIGS. 6A-6B illustrate an example process of mounting a die produced using the example process of FIGS. 5A-5C in an example exposed die package.

FIGS. 7A-7C illustrate another example procedure to cut dies with interlocking sides from an example wafer.

### DETAILED DESCRIPTION

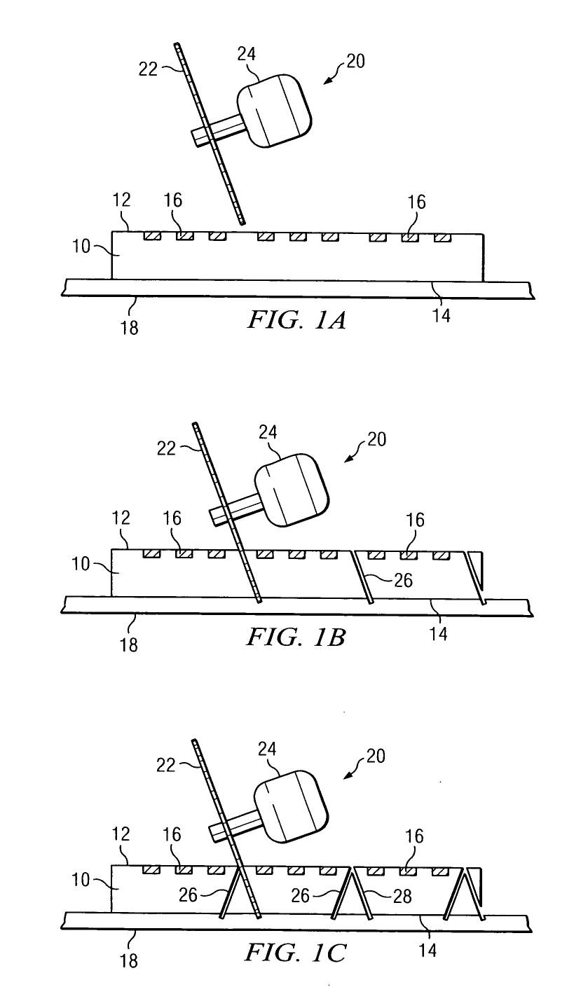

FIGS. 1A-1C illustrate an example procedure performed by an example semiconductor wafer handling system to cut dies or chips from a wafer 10. In the illustrated example, the example dies are cut to exhibit interference structures at their edges and, thus, are particularly well suited to be packaged in an exposed die package. When so packaged, the example dies illustrated herein exhibit improved retention robustness against external pulling forces. Thus, exposed die packages incorporating one or more of the example dies illustrated herein exhibit improved resistance to delamination due to pulling forces.

In the example of FIG. 1A, the wafer 10 has an active top surface 12 and a bottom surface 14. The wafer 10 is fabricated to include a plurality of dies (also referred to as “chips”). Each of the dies includes one or more active elements, passive elements, or both active and passive elements such as one or more transistors, capacitors, inductors, resistors, etc. coupled in one or more circuits. The circuit(s), the electrical elements or both the circuits and electrical elements may be fabricated by one or more semiconductor processes to form any desired circuitry. Some or all of the circuits, electrical elements, or both the circuits and electrical elements of the dies may be exposed on the active top surface 12, while some or all of the circuits and electrical elements of the dies may be embedded within one or more lower surfaces of the wafer 10. Each die of the illustrated example also includes one or more bonding pads 16 on the active top surface 12 of the wafer 10 that allow electrical interconnection with the components, the circuits or with both the components and the circuits of the corresponding die.

In the example of FIG. 1A, the wafer 10 is mounted on an example wafer frame 18. In particular, the bottom surface 14 of the wafer 10 is in contact with the wafer frame 18. In this example, the bottom surface 14 of the wafer 10 is removably secured to the wafer frame 18 by a chemical adhesive such as tape. The wafer frame 18 of the illustrated example is mounted on a chuck (not shown) by vacuum force or mechanical mounting mechanism. The chuck is part of a stepper mechanism which is structured to laterally move, rotate, or both move and rotate the wafer frame 18 and, thus, the wafer 10.

Guide lines are marked on the active top surface 12 of the wafer 10 in order to provide a guide path for a cutting device such as a saw 20. In the illustrated example, the guide lines are positioned to define boundaries between the dies fabricated on the wafer 10. Further, the saw 20 is provided with machine vision capability and a positioning mechanism which, together with a controller, operate to cut the wafer 10 into dies in accordance with the guide lines. More specifically, the saw 20 includes a cutting blade 22 and a positioning mechanism 24 (e.g., a servo motor) that moves the cutting blade 22 between a resting position above the wafer 10 (e.g., the position shown in FIG. 1A) and a cutting position in the wafer 10 (e.g., the position shown in FIG. 1B). In the illustrated example, the blade 22 of the saw 20 is tilted at an angled position relative to the upper surface 12 of the wafer 10. In the example of FIGS. 1A-1C, the blade 22 of the saw 20 is angled at approximately 45 degrees relative to the upper surface 12. However, persons of ordinary skill in the art will readily appreciate that other (e.g., non-ninety degree) angles may alternatively be employed. Persons of ordinary skill in the art will further recognize that, although a mechanical saw 20 is illustrated in the example of FIGS. 1A-1C, other cutting devices such as a laser may alternatively be used to cut the wafer 10.

FIG. 1B shows the saw 20 in a cutting position with the cutting blade 22 lowered into the wafer 10. As noted above, the saw 20 is at an angled position. Therefore, the saw 20 makes an angled cut 26 on one side of a die formed in the wafer 10. The saw 20 is repeatedly used to make angled cuts 26 through the wafer adjacent the sides of each of the dies in accordance with the guide marking made on the surface 12 of the wafer 10. In the example of FIG. 1B, the saw 20 is shown making a second angled cut after having made a first angled cut 26 in the wafer 20.

The stepper mechanism reorients the wafer 10 periodically to enable the saw 20 to cut other sides of the dies. Persons or ordinary skill in the art will appreciate that the stepper mechanism can operate in any number of manners to cut the wafer 10 in any desired sequence of cuts to make any desired pattern. For example, the stepper mechanism may rotate the wafer 10 such that the saw 22 cuts the wafer 10 in a concentric circular pattern, such that the saw 22 makes all of the parallel cuts of the wafer 10 before rotating (e.g., the first sides of all the dies are cut before any of the second sides are cut, the second sides of all the dies are cut before any of the third sides are cut, etc.), or in any other desired way. In the illustrated example, the dies have four sides and, thus, the stepper mechanism rotates the wafer 10 by 90 degrees to move from cutting a first side of a die to a second side of a die. However, other movements would be appropriate if, for example, other die geometries are desired. Further, in the illustrated example of FIGS. 1A-1C, the angular position of the saw 20 is fixed for all cuts. However, persons of ordinary skill in the art will readily appreciate that the angular position of the saw may be changed for different cuts (e.g., different sides of a given die may have different angular edges), if desired. Additionally, although in the illustrated example, the saw 20 is moved linearly relative to the wafer to make the cuts (e.g., along the plane of the paper showing FIGS. 1A and 1B and perpendicularly to the plane of the paper), persons of ordinary skill in the art will appreciate that other movements are likewise appropriate (e.g., moving the wafer relative to the saw 20 while keeping the saw fixed, etc.).

FIG. 1C illustrates the example wafer 10 after it has been reoriented by the stepper mechanism by 180 degrees from FIGS. 1A and 1B. In the illustrated example, the saw 20 cuts along the guide lines for each of the dies to create a second set of angled cuts 28. The cutting of the wafer 10 continues in this manner until each side or edge of each die has been cut so that all desired dies are separated from the wafer 10 and from one another. Persons of ordinary skill in the art will recognize that it may be desirable to cut some sides of the dies differently than others. For example, the dies may be cut to have two angled sides or edges and two substantially vertical sides, with the angled sides being located on opposite sides of the die from each other and the straight sides being oriented at substantially 90 degrees to the angled sides. In such an approach, after the angled cuts 26 and 28 are completed, the wafer 10 is rotated 90 degrees and the saw 20 is reoriented to a substantially vertical plane relative to the upper surface 12 of the wafer 10. The saw 20 is then used to make substantially vertical cuts (i.e., cuts oriented substantially perpendicular to the surface of the wafer 10) to complete cutting the dies from the wafer 10.

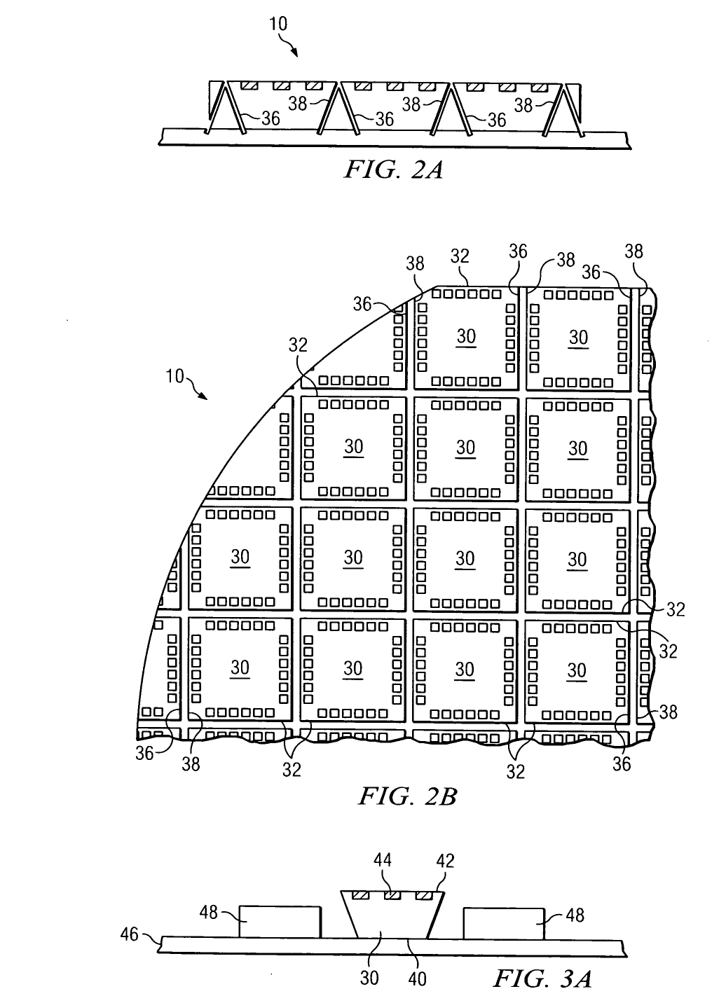

As shown in FIGS. 2A-2B, after the sawing process is completed, the wafer 10 has been separated into individual example dies or chips 30. The example dies 30 have angled sides 36 and 38 which are formed by the cuts 26 and 28 and substantially vertically oriented sides 32 which are formed by the perpendicular cuts discussed above. After the procedure shown in FIGS. 1A-1C, the wafer frame 18 is stretched to separate the dies from one another. The individual dies 30 are then picked up via, for example, a vacuum pickup, for further processing.

Persons of ordinary skill in the art will appreciate that other saw configurations can be used to cut dies whose sides form mold lock interference structures. For example, geometry similar to that produced by the method illustrated in FIGS. 1A-1C could be achieved by using a single, V-shaped blade to simultaneously cut two sides of adjacent dies at opposite angles. Such a cut could be made, for example, from the back side of the wafer. In addition, although the above examples illustrates mold lock interference structures formed by substantially monotonic, angled sides, other geometries could be used to produce interference structures. For instance, as described below, the dies may be cut with stepped sides which function as mold lock interference structures.

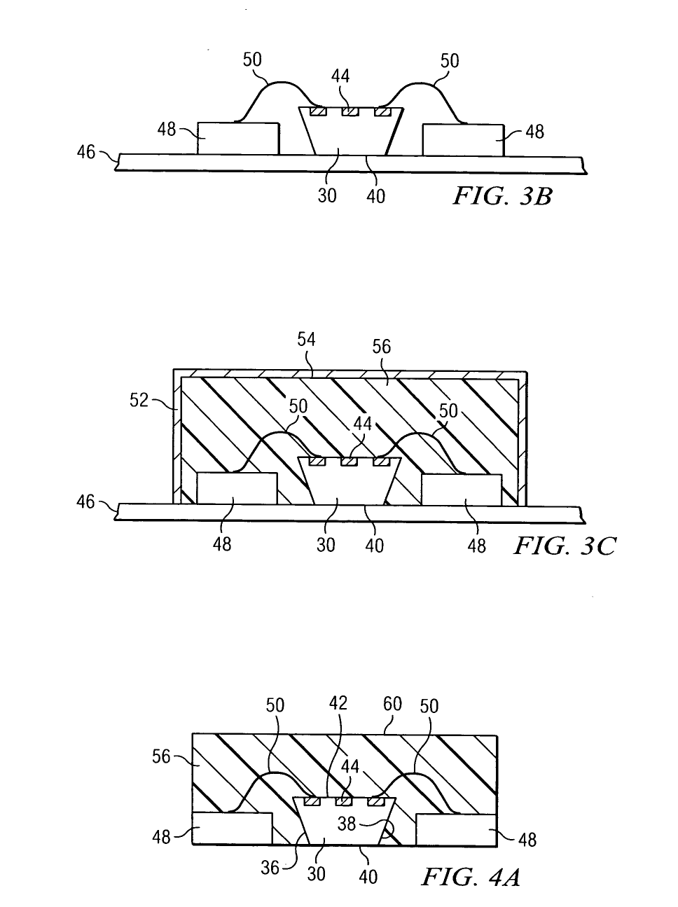

FIG. 3A shows an individual example die 30 which has been fabricated via the process of FIGS. 1A-1C. The example die of FIG. 3A has a bottom surface 40 and an active top surface 42. The die 30 includes the circuitry formed in processing the wafer 10. The active top surface 42 of the illustrated example has bond pads 44 for making electrical connections to the die 30. The bottom surface 40 is mounted on a die carrier 46 such as, for example, sticky carrier tape. In the example of FIG. 3A, other structures 48 (e.g., mounting pads, other dies, etc.) are placed on the die carrier 46 adjacent the sides of the die 30.

FIG. 3B shows wires 50 bonded between the bond pads 44 on the die 30 and the adjacent structures 48. In the illustrated example, the adjacent structures 48 are contact pads which provide external electrical connections to the die 30. Persons of ordinary skill in the art will recognize that there are other mechanisms for electrical connection to the die 30. For instance, although the illustrated example employs wire bonding, other bonding techniques may alternatively or additionally be employed.

FIG. 3C illustrates the example die 30 and adjacent structures 48 after an example mold 52 has been is lowered over the die 30 and the structures 48. The example mold 52 of FIG. 3C rests on the die carrier 46. The mold 52 defines a mold cavity 54 which surrounds the die 30 and the mounting pads 48. Encapsulating material (e.g., a plastic pellet) is injected into the mold cavity 54 and melted. The melted encapsulating material 56 flows throughout the mold cavity 54 to encapsulate the die 30 and the mounting pads 48 and form an exposed die package. After the encapsulating material is solidified, the mold 52 and the die carrier 46 are removed from the die package and excess encapsulating material is removed via cutting or grinding to finish the exposed die package.

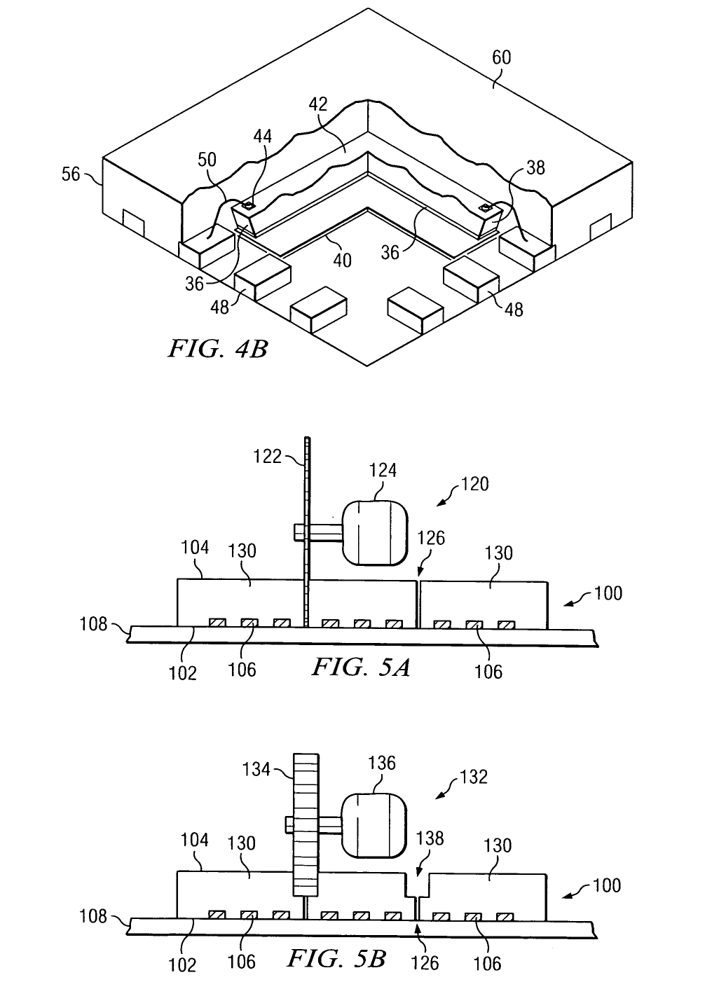

FIGS. 4A and 4B are a side view and a perspective cutaway view, respectively, of the completed exposed die package 60 of FIG. 3C after removal from the carrier 46. In the illustrated example, the active top surface 42 of the die 30 is completely encapsulated by the encapsulating material 56. The mounting pads 48 provide external electrical connections via the wires 50 and the bond pads 44 to the electrical elements, the circuits, or to both the circuits and electrical elements of the die 30. As shown in FIG. 4B, although the bottom surface of the die 30 is exposed, the angled sides 36 and 38 of the die 30 are interlocked with the encapsulating material 56 in the die package 60 to prevent movement of the die 30 relative to the die package 60 from the exposed bottom surface. This mold lock reduces the likelihood of delamination of the exposed die package 60 due to external pulling forces.

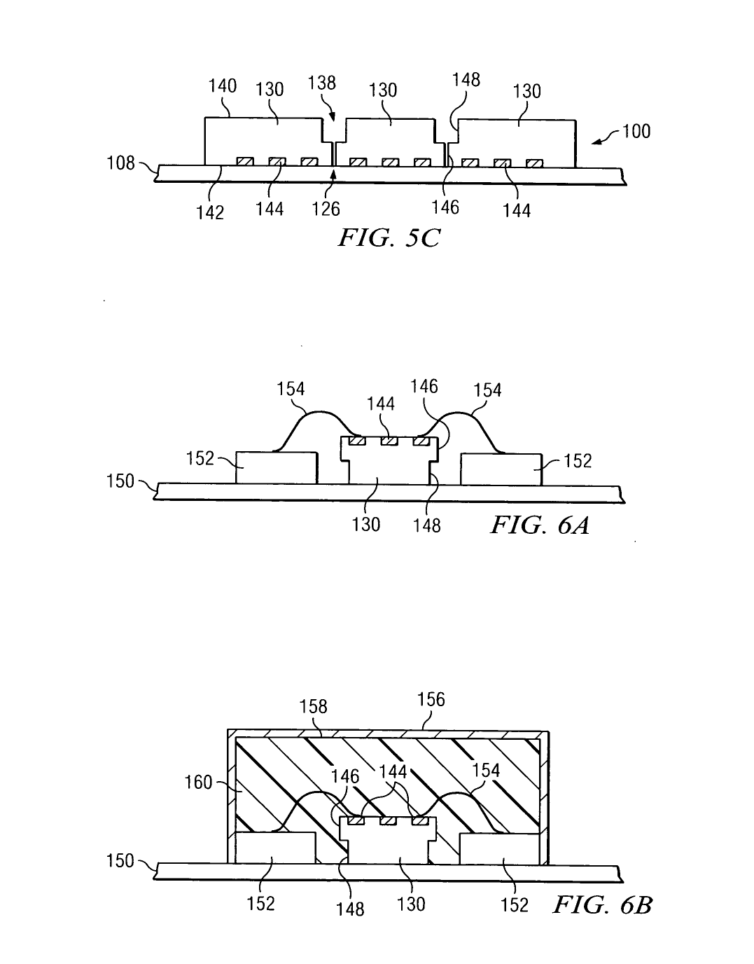

FIGS. 5A-5C illustrate another example process to cut dies or chips from an example wafer 100 to facilitate mold locking of the same in, for example, an exposed die package. Unlike the example of FIGS. 1A-1B, in the example of FIGS. 5A-5C, the wafer 100 is inverted. The example wafer 100 of FIG. 5A has an active top surface 102 and a bottom surface 104. The wafer 100 is fabricated to include a plurality of dies (also referred to as “chips”). Each of the dies includes one or more electrical elements such as one or more transistors, capacitors, inductors, resistors, etc. coupled in one or more circuits. The circuit(s), the electrical elements, or both the circuits and electrical elements may be fabricated by one or more semiconductor processes to form any desired circuitry. Some or all of the circuits and electrical elements of the dies may be exposed on the active top surface 102, while some or all of the circuits and electrical elements of the dies may be embedded within one or more lower surfaces of the wafer 100. Each die of the illustrated example also includes one or more bonding pads 106 on the active top surface 102 of the wafer 100 that allow electrical interconnection with the some or all of the components and circuits of the corresponding die. In FIG. 5A, the wafer 100 has been inverted on an example wafer frame 108 to place the active top surface 102 in contact with the wafer frame 108. The active top surface 102 may be mounted on the wafer frame 108 by non-destructive methods such as applying ultra-violet release adhesive. The wafer frame 108 is mounted on a chuck (not shown) by mechanisms such as vacuum force or mechanical mechanism. The chuck is part of a stepper mechanism which is structured to laterally move, rotate or both laterally move and rotate the wafer frame 108 and, thus, the wafer 100.

Precise guide lines are marked on the bottom surface 104 of the wafer 100 in order to provide a guide path for cutting out the individual dies from the wafer 100. In this example, the guide lines may be inscribed using an infra-red sensor to align the guidelines with the circuit features on the active surface 102. Of course persons of ordinary skill in the art will recognize that other alignment and/or inscription mechanisms may be used to ensure that the dies are properly cut from the wafer 100.

In the example of FIG. 5A, the example saw 120 includes a thin cutting blade 122 and a positioning mechanism 124 to move the thin cutting blade 122 between a resting position above the wafer 100 and a cutting position in the wafer 100. FIG. 5A shows the saw 120 making a first series of parallel, substantially vertical, thin cuts 126 which extend to the carrier frame 108. After the first series of parallel cuts 126, the wafer 100 is rotated 90 degrees and a second series of thin cuts 126 are made. The second series of thin cuts 126 are substantially perpendicular to the first series of cuts. After the first and second series of thin cuts 126 are made, all fours sides of the dies have been cut and, thus, the individual dies 130 have been cut from the wafer 100.

FIG. 5B shows an example saw 132 with a thick cutting blade 134. The example saw 132 has a positioning mechanism 136 which moves the thick cutting blade 134 between a resting position above the wafer 100 and a cutting position in the wafer 100 (e.g., the position shown in FIG. 5B). The same stepper mechanism and wafer frame 100 are used in FIGS. 5A and 5B. The saw of FIG. 5A may be the same saw shown in FIG. 5B with a different saw blade, or two different saws may be employed (e.g., the wafer frame 108 and wafer 100 may be moved to another stepper mechanism).

The saw 132 makes a series of thick cuts 138 in communication with and parallel to one or both of the first and second series of thin cuts 126. As shown in FIG. 5B, the thick cuts 138 are made at a shallower depth than the thin cuts 126 and, thus, the thick saw 132 does not reach the carrier frame 108. In this example, the thick cuts 138 extend to about half the thickness of the wafer 100, but persons of ordinary skill in the art will appreciate that other depths are likewise appropriate. Although, of course, they are not required, in the illustrated example, after the saw 132 makes the first series of thick cuts 138, the wafer 100 is rotated by 90 degrees, and the saw 132 makes a second series of thick cuts perpendicular to the first series of thick cuts 138. As with the first series of thin cuts and the first series of thick cuts, the second series of thick cuts is aligned with the second series of thin cuts 126 to form channels having a profile such as those shown in FIG. 5B.

As shown in FIG. 5C, after the cutting process in FIGS. 5A-5B, the wafer 100 has been separated into individual chips or dies 130 by the cuts 126 and those dies 130 have stepped edges due to the thick cuts 138. In the example of FIG. 5C, the dies 130 are still inverted on the carrier frame 108 and, thus, each die has a bottom surface 140 face up and an active top surface 142 face down in contact with the carrier frame 108. The active top surface 142 of each die includes the bond pads 144. The dies 130 each have an upper wall 146 in proximity to the active top surface 142 and a recessed lower wall 148 in proximity to the bottom surface 140 which are formed by the cuts 126 and 138, respectively. The upper and lower walls 146, 148 combine to form the stepped edges of the dies. After the cutting procedures shown in FIGS. 5A-5B, the wafer frame 108 is stretched to separate the dies 130, and the individual dies 130 are then picked up via, for example, a vacuum pickup for packaging and further processing.

FIG. 6A shows an example die 130 which has been fabricated via the process of FIGS. 5A-5C. The example die of FIG. 6A has been inverted to place the bottom surface 140 on a die carrier 150 so the active top surface 142 is face up. Other structures (e.g., contact pads) 152 are placed on the die carrier 148 adjacent the walls 146 and 148 of the die 130. Wires 154 are bonded on the bond pads 144 and the adjacent structures 152, which, in this example, are contact pads to provide external electrical connections to the die 130.

FIG. 6B illustrates the example die 130 and adjacent structures 152 after a mold 156 that has been lowered over the die 130 and the structures 152. The mold 156 defines a mold cavity 158 which surrounds the die 130 and the mounting pads 152. Encapsulating material such as plastic is injected into the mold cavity 156 and melted. The melted encapsulating material 160 flows throughout the mold cavity 156 to encapsulate the die 130 and the structures 152. After the encapsulating material 160 has solidified, the die carrier 150 and mold 156 are removed and excess encapsulating material is eliminated via cutting or grinding to finish the exposed die package.

As shown in FIG. 6B, the lower recessed sides 148 of the die 130 form a mold lock with the encapsulating material 160 to prevent movement of the die 130 relative to the encapsulating material 160 thereby providing a robust exposed die package.

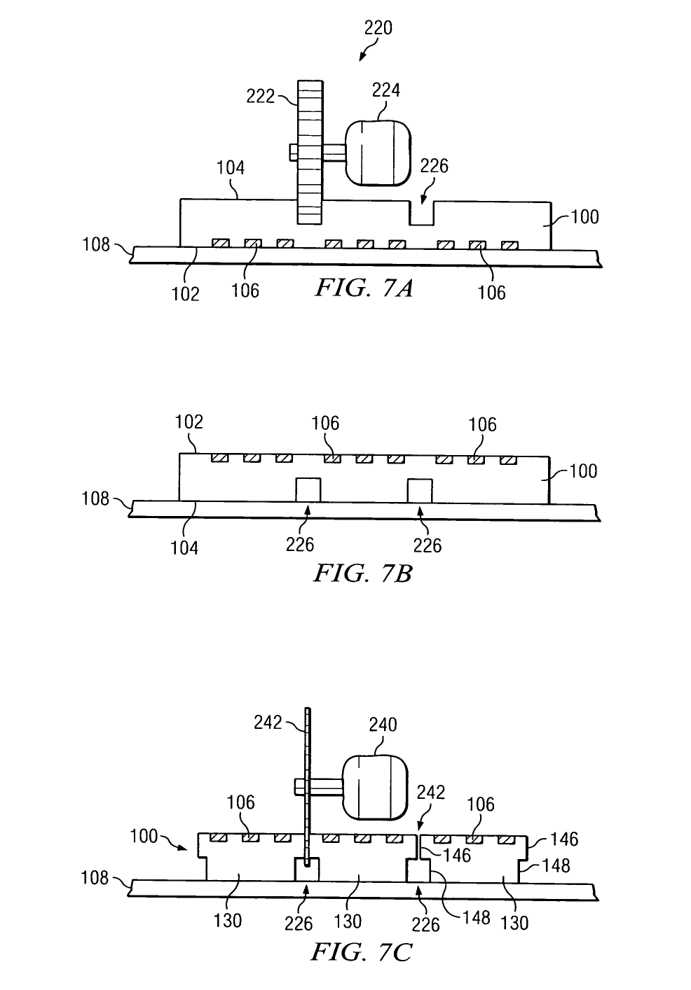

FIGS. 7A-7C show an alternate example process to cut the die 130 shown in FIGS. 6A-6B from the wafer 100. In the example of FIG. 7A, the wafer 100 has been mounted on an example wafer frame 108 with the active top surface 102 in contact with the wafer frame 108. As previously explained, the active top surface 102 may be mounted on the wafer frame 108 by non-destructive methods such as a ultra-violet release adhesive. The wafer frame 108 is mounted on a chuck of a stepper mechanism which allows lateral movement and rotation of the wafer frame 108 and wafer 100.

Guide lines are marked on the bottom surface 104 of the wafer 100 in order to provide a guide path for sawing the individual chips in the wafer 100. The guide lines may be inscribed by alignment with a flat edge of the wafer 100, partial marking cuts or other suitable methods for aligning cuts to the features of the active top surface 102. Of course persons of ordinary skill in the art will recognize that other alignment and/or inscription mechanisms may be used.

In the illustrated example, an example saw 220 includes a thick cutting blade 222 and a positioning mechanism 224 to move the blade 222 between a resting position above the wafer 100 and a cutting position within the wafer 100. In the example of FIG. 7A, the saw 220 makes a thick, substantially vertical, cut 226 which extends partially into the wafer 100. In this example, the thick cut 226 extends approximately half the thickness of the wafer 100, but other depths may be used. After making a first set of thick cuts 226 in one direction, the wafer 100 is rotated by 90 degrees and the saw 200 is used to make a second set of cuts. The second set of cuts are substantially similar to the first set of cuts, but the first and second set of cuts are substantially perpendicular to one another. After making the first and second set of cuts, the wafer 100 is demounted from the carrier frame 108, cleaned and reattached to the same or different carrier frame 108 in an inverted position relative to FIG. 7A.

FIG. 7B shows the example wafer 100 in the inverted position with the bottom surface 104 now in contact with a carrier frame 108. The active top surface 102 is now face up allowing precise alignment of guide lines for the next set of cuts described below.

FIG. 7C shows an example saw 240 with a thin cutting blade 242 for making thin cuts. As in the example of FIGS. 6A-6C, the same stepper mechanism may be used with a different cutting blade 242 for making the thin cuts. Alternatively, the wafer frame 108 and wafer 100 may be moved to another stepper mechanism with a different saw such as the saw 240.

In the illustrated example, the saw 240 makes a number of thin cuts 242 which extend into the thick cuts 126. After making a series of thin cuts 126 in one direction, the wafer 100 is rotated by 90 degrees and a second series of thin cuts is made. The second series of thin cuts are substantially perpendicular to the first series of thin cuts, and are in communication with the second series of thick cuts in a like manner to the first series of thin cuts and the first series of thick cuts shown in FIG. 7C. In this manner, individual dies 130 are formed to have upper and recessed lower walls 146 and 148. The cut out dies 130 are then encapsulated in exposed die packages in the manner explained above in connection with FIGS. 6A-6B.

From the foregoing, persons of ordinary skill in the art will appreciate that example semiconductor dies and example methods of mold locking semiconductor dies have been disclosed. The example semiconductor dies disclosed herein include one or more non-vertical edges that function as one or more interference structures to help secure the die within a semiconductor package. The disclosed examples are particularly advantageous in the context of exposed die packages wherein the die is exposed at a surface of the package. More specifically, prior art dies have vertical sides. Therefore, these prior art dies are not mold locked in an exposed die package, but instead can be moved vertically out of the molded package in response to a relatively small external pull force. If the external pull force is sufficient, delamination can result and the prior art die may slip out of the package.

In contrast, the example dies illustrated herein include one or more interference structures at one, two, three, or four edges positioned and oriented to enable the molding compound to solidify between the interference structures and the exposed package surface. As a result, an exposed die package incorporating an example die as illustrated herein, exhibits improved robustness against delamination caused by external pull forces relative to prior art dies.

Although the foregoing examples focused on example dies in wire bonding applications, persons of ordinary skill in the art will readily appreciate that the teachings of this disclosure are not limited to any particular die structure or bonding technique. On the contrary, the teachings of this disclosure may be applied to other types of bonding techniques or other types of dies including, for instance, flip chips. Thus, for example, the teachings of this disclosure may be applied to any package wherein the bottom of a die is exposed to the surface for mounting on a board or external heat sink (e.g., wherein the backside of the wafer is a solderable surface such as a back side metal) or to packages wherein the top side of the die is exposed (e.g., flip chip applications).

Also, although the above examples illustrate the use of mechanical saws to create interference profiles on the edges of dies, other sawing mechanisms such as laser cutting mechanisms may be alternatively and/or additionally employed.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. A semiconductor die comprising:
a top surface;
a bottom surface;
a plurality of sides joining the top surface and the bottom surface, at least one of the sides comprising an interference structure to mold lock the die in a package.

2. The die of claim 1 wherein the interference structure comprises an angled surface disposed at a non 90 degree angle relative to at least one of the top surface and the bottom surface.

3. The die of claim 2 wherein the angled surface is disposed at an acute angle relative to at least one of the top surface and the bottom surface.

4. The die of claim 3 wherein the acute angle is approximately 45 degrees.

5. The die of claim 1 wherein the interference structure comprises a stepped side wall.

6. The die of claim 5 wherein the stepped side wall comprises a lower recessed wall in proximity to the bottom surface and an upper wall in proximity to the top surface.

7. The die of claim 1 wherein the package comprises encapsulating material molded around the die.

8. The die of claim 7 wherein the encapsulating material is located on at least two opposed sides of the die.

9. The die of claim 1 wherein the interference structure forms the at least one of the sides of the die.

10. The die of claim 9 wherein the interference structure includes at least two inwardly angled sides.

11. The die of claim 10 wherein the at least two inwardly angled sides are located on opposite sides of the die.

12. The die of claim 11 wherein the sides include at least two substantially vertical sides.

13. The die of claim 1 wherein the package is an exposed die package such that one of the top surface or the bottom surface of the die is disposed at a surface of the exposed die package.

14. A method of forming a semiconductor device comprising:
cutting a wafer to define an interference structure at at least one side of a die; and
separating the die from the wafer.

15. The method of claim 14 wherein cutting the wafer comprises cutting the wafer with at least one of a mechanical saw or a laser.

16. The method of claim 14 further comprising:
positioning the separated die on a die carrier;
mounting an electrical element on the die carrier in proximity to the die; and
attaching a wire bond between the electrical element and the die.

17. The method of claim 16 further comprising:
placing a mold over the die and the electrical element; and
injecting an encapsulating material into the mold to mold lock the die in a package.

18. The method of claim 17, wherein the interference structure of the die prevents the die from moving relative to the encapsulating material.

19. The method of claim 18, wherein the package is an exposed die package and the electrical element is a contact pad.

20. The method of claim 14 wherein cutting the wafer to define the interference structure at the at least one side of the die comprises cutting the wafer at a angle relative to the top surface and bottom surface, the angle being different from 90 degrees.

21. The method of claim 14 wherein cutting the wafer to define the interference structure at the at least one side of the die comprises:
making a first cut in the wafer at a first width and to a first depth; and
making a second cut in the wafer at a second width and to a second depth, the second width being wider than the first width and the second depth being less than the first depth.

22. The method of claim 21, wherein the first cut is made in a bottom surface of the wafer, and the second cut is made on the top surface of the wafer.

23. The method of claim 22, further comprising inverting the wafer after making the first cut.

24. The method of claim 21, wherein the first cut and the second cut are made in a bottom surface of the wafer.

25. An exposed die package comprising:
a die having a side defining an interference structure; and
an encapsulating material at least partially engaging the interference structure to mold lock the die in the package.

26. The die package of claim 25, wherein the die further comprises a bond pad and further comprising a contact pad in electrical communication with the bond pad, the contact pad being accessible from external the package to provide electrical connection to the die.

27. The die package of claim 25 wherein the interference structure is angled relative to a surface of the die.

28. The die package of claim 25 wherein the interference structure comprises a stepped surface.

29. The die package of claim 25 wherein the die includes a bottom surface which is substantially flush with a bottom surface of the encapsulating material.
